(19) United States
(12) Patent Application Publication
(10) Pub. No.: US 2019/0149124 A1
(43) Pub. Date: May 16, 2019

(54) PIEZOELECTRIC VIBRATING PIECE AND PIEZOELECTRIC DEVICE

(71) Applicant: NIHON DEMPA KOGYO CO., LTD., Tokyo (JP)

(72) Inventors: Shigetaka KAGA, Saitama (JP); Masaaki NAKAHARA, Saitama (JP)

(73) Assignee: NIHON DEMPA KOGYO CO., LTD., Tokyo (JP)

(21) Appl. No.: 16/188,313

(22) Filed: Nov. 13, 2018

(30) Foreign Application Priority Data
Nov. 16, 2017 (JP) 2017-221018
Aug. 23, 2018 (JP) 2018-155923

(51) Int. Cl. H03H 9/13; H03H 9/02; H03H 9/10; H03H 9/19

(52) U.S. Cl. CPC H03H 9/132; H03H 9/19; H03H 9/105; H03H 9/02023

(57) ABSTRACT

A piezoelectric vibrating piece includes a piezoelectric substrate and excitation electrodes. The piezoelectric substrate is formed in a flat plate shape and vibrates in a thickness-shear vibration mode. The excitation electrodes are formed on respective both principal surfaces of the piezoelectric substrate and each include a main thickness portion and a flat portion. The main thickness portion has a first thickness. The flat portion is formed in a peripheral area of the main thickness portion and has a second thickness that is thinner than the first thickness between from a portion contacting the main thickness portion to an outermost periphery of the excitation electrode, extends from the portion contacting the main thickness portion to the outermost periphery of the excitation electrode, and has a width formed to have a length of 0.63 times or more and 1.88 times or less of a flexural wavelength of an unnecessary vibration.

### CROSS-REFERENCE TO RELATED APPLICATIONS

This application is based on and claims priority under 35 U.S.C. § 119 to Japanese Patent Application No. 2017-221018, filed on Nov. 16, 2017, and Japanese Patent Application No. 2018-155923, filed on Aug. 23, 2018, and the entire contents of which are incorporated herein by reference.

### TECHNICAL FIELD

This disclosure relates to a piezoelectric vibrating piece including an inclined portion in a peripheral area of an excitation electrode and relates to a piezoelectric device.

### DESCRIPTION OF THE RELATED ART

A piezoelectric vibrating piece, which includes an excitation electrode on a piezoelectric substrate, is formed in a convex shape having a thin thickness in a peripheral area of the piezoelectric substrate, and thus confines a vibration energy, thereby ensuring reduced unnecessary vibration. However, forming the piezoelectric substrate into the convex shape causes a problem of labor and cost increase in processing.

In contrast to this, Japanese Unexamined Patent Application Publication No. 2002-217675 discloses that while a piezoelectric substrate still has a flat plate shape, a peripheral area of an excitation electrode is formed in an inclined-surface shape where a thickness of the excitation electrode gradually decreases, thus reducing the labor and cost of the processing of the piezoelectric substrate.

However, even when the inclined surface shape as described in Japanese Unexamined Patent Application Publication No. 2002-217675 is formed, it has been found that the effect that reduces an unnecessary vibration substantially differs depending on dimensions of the inclined-surface shape. That is, there has been a problem where simply forming the peripheral area of the excitation electrode in an inclined-surface shape does not ensure the sufficiently reduced unnecessary vibration.

A need thus exists for a piezoelectric vibrating piece and a piezoelectric device which are not susceptible to the drawback mentioned above.

### SUMMARY

According to an aspect of this disclosure, there is provided a piezoelectric vibrating piece that includes a piezoelectric substrate and excitation electrodes. The piezoelectric substrate is formed in a flat plate shape. The piezoelectric substrate vibrates in a thickness-shear vibration mode. The excitation electrodes are formed on respective both principal surfaces of the piezoelectric substrate. The excitation electrodes each include a main thickness portion and a flat portion. The main thickness portion has a first thickness. The flat portion is formed in a peripheral area of the main thickness portion. The flat portion has a second thickness that is thinner than the first thickness between from a portion contacting the main thickness portion to an outermost periphery of the excitation electrode. The flat portion having the second thickness extends from the portion contacting the main thickness portion to the outermost periphery of the excitation electrode. The flat portion having a width formed to have a length of 0.63 times or more and 1.88 times or less of a flexural wavelength, the flexural wavelength being a wavelength of a flexure vibration as an unnecessary vibration.

### BRIEF DESCRIPTION OF THE DRAWINGS

The foregoing and additional features and characteristics of this disclosure will become more apparent from the following detailed description considered with reference to the accompanying drawings, wherein:

FIG. 1A is a perspective view of a piezoelectric device 100;

FIG. 1B is a perspective view of the piezoelectric device 100 from which a lid 120 is removed;

FIG. 2 is an explanatory drawing of an M-SC-cut quartz-crystal material;

FIG. 3A is a plan view of piezoelectric vibrating pieces 140 and 240 including a flat portion and an inclined portion in an outer periphery of an excitation electrode;

FIG. 3B is a sectional drawing taken along the line IIIB-IIIB in FIG. 3A;

FIG. 4A is a plan view of the piezoelectric vibrating piece 240 including only a flat portion in the outer periphery of the excitation electrode;

FIG. 4B is a sectional drawing taken along the line IVB-IVB in FIG. 4A;

FIG. 5A is a graph showing a relationship between a width XB of a flat portion 242b and a vibration energy loss (1/Q) when the piezoelectric vibrating piece 240, which is illustrated in FIG. 3A and FIG. 3B, vibrates in the fundamental wave;

FIG. 5B is a graph showing a relationship between the width XB of the flat portion 242b and the vibration energy loss (1/Q) when the piezoelectric vibrating piece 240, which is illustrated in FIG. 4A and FIG. 4B, vibrates in the fundamental wave;

FIG. 6A is a first example that includes an excitation electrode in the piezoelectric vibrating piece 240;

FIG. 6B is a second example that includes an excitation electrode in the piezoelectric vibrating piece 240;

FIG. 6C is a graph showing an actually measured thickness of an excitation electrode of an experimentally produced piezoelectric vibrating piece 240;

FIG. 7 is a graph showing a consequence of CI variation amounts by temperature changes on the experimentally produced piezoelectric vibrating pieces 240 illustrated in FIG. 3A and FIG. 3B, and comparative piezoelectric vibrating pieces to which the embodiment is not applied;

FIG. 8A is a drawing showing a whole picture of CI temperature characteristics for nine pieces of piezoelectric devices of a comparative example (the comparative piezoelectric vibrating piece to which the embodiment is not applied);

FIG. 8B is a drawing showing a whole picture of CI temperature characteristics for nine pieces of piezoelectric devices of a working example where an electrode structure of the piezoelectric vibrating piece 240, which is illustrated in FIG. 3A and FIG. 3B, was reassembled;

FIG. 9A is a graph showing a relationship between the width XB of the flat portion 242b and the vibration energy loss (1/Q) when an M-SC-cut piezoelectric vibrating piece 240 vibrates in the fifth harmonic, and

FIG. 9B is a graph showing a relationship between the width XB of the flat portion 242b and the vibration energy loss (1/Q) when an IT-cut piezoelectric vibrating piece 240 vibrates in the fifth harmonic.

### DETAILED DESCRIPTION

The embodiments of this disclosure will be described in detail with reference to the drawings. The embodiments in the following description do not limit the scope of the disclosure unless otherwise stated.

[AT-Cut]

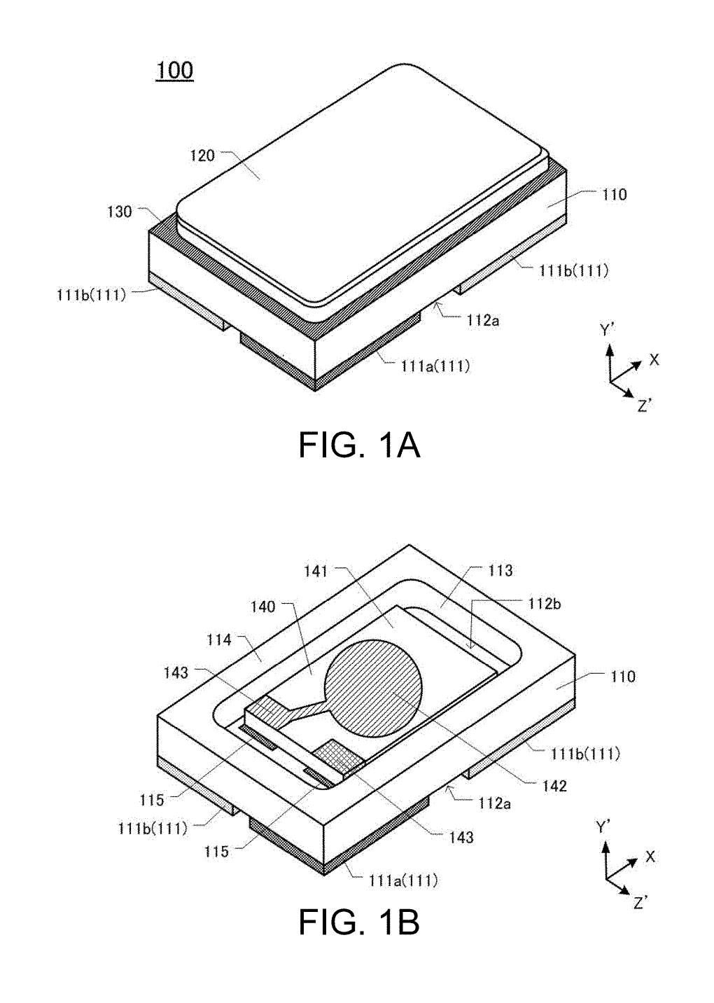

FIG. 1A is a perspective view of a piezoelectric device 100. The piezoelectric device 100 includes, mainly, a base 110, a lid 120, and a piezoelectric vibrating piece 140 (see FIG. 1B) that vibrates at a predetermined vibration frequency. An outer shape of the piezoelectric device 100 is formed in, for example, an approximately rectangular parallelepiped shape. The piezoelectric vibrating piece 140 is formed using an AT-cut quartz-crystal material that vibrates in a thickness-shear vibration mode as a base material. The AT-cut quartz-crystal material is formed having a principal surface (XZ surface) that is rotated by 35° 15′ from a Z-axis toward a −Y-axis direction around an X-axis with respect to a Y-axis of crystallographic axes (XYZ). In the following descriptions, new axes where the AT-cut quartz-crystal material is inclined are denoted as a Y′-axis and a Z′-axis. The piezoelectric device 100 illustrated in FIG. 1A is formed such that a longitudinal direction is an X-axis direction, a height direction of the piezoelectric device 100 is a Y′-axis direction, and a direction perpendicular to the X-axis direction and the Y′-axis direction is a Z′-axis direction.

The base 110 has a mounting surface 112a on a −Y′-axis side as a surface on which the piezoelectric device 100 is mounted, and mounting terminals 111 are formed on the mounting surface 112a. The mounting terminals 111 include hot terminals 111a as terminals connected to the piezoelectric vibrating piece 140, and terminals (hereinafter temporarily referred to as grounding terminals) 111b that are usable for grounding. The base 110 includes the respective hot terminals 111a in a corner on a +X-axis side and a −Z′-axis side and a corner on a −X-axis side and a +Z′-axis side of the mounting surface 112a. The base 110 includes the respective grounding terminals 111b in a corner on the +X-axis side and the +Z′-axis side and a corner on the −X-axis side and the −Z′-axis side of the mounting surface 112a. On a surface of a +Y′-axis side of the base 110, a cavity 113 is formed (see FIG. 1B) as a space where the piezoelectric vibrating piece 140 is placed, and the cavity 113 is sealed by the lid 120 via a sealing material 130.

FIG. 1B is a perspective view of the piezoelectric device 100 from which the lid 120 is removed. The cavity 113, which is formed on the surface of the +Y′-axis side of the base 110, is surrounded by a placement surface 112b and a sidewall 114. The placement surface 112b, on which the piezoelectric vibrating piece 140 is placed, is a surface on an opposite side of the mounting surface 112a. The sidewall 114 is formed in a peripheral area of the placement surface 112b. The placement surface 112b includes a pair of connection electrodes 115 electrically connected to the hot terminals 111a.

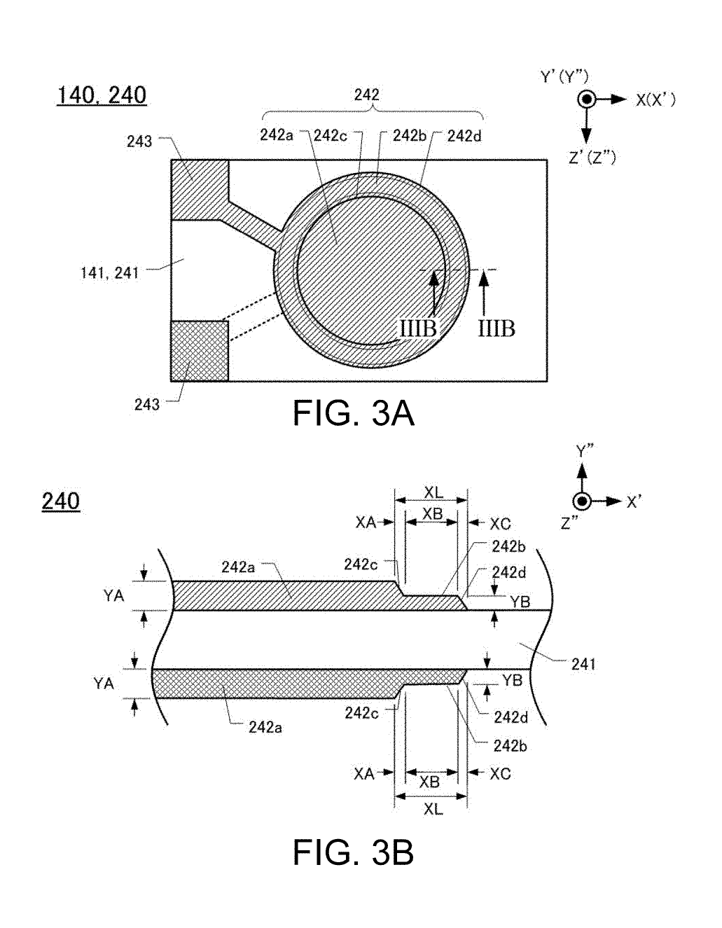

The piezoelectric vibrating piece 140 includes a piezoelectric substrate 141, excitation electrodes 142, and extraction electrodes 143. The piezoelectric substrate 141 is formed in a flat plate shape and vibrates in a thickness-shear vibration mode. The excitation electrodes 142 are formed on respective principal surfaces on the +Y′-axis side and the −Y′-axis side of the piezoelectric substrate 141. The extraction electrodes 143 are extracted to both ends of a side on the −X-axis side of the piezoelectric substrate 141 from the respective excitation electrodes 142. The excitation electrode 142 formed on a surface on the +Y′-axis side of the piezoelectric substrate 141 and the excitation electrode 142 formed on a surface on the −Y′-axis side of the piezoelectric substrate 141 are formed in identical shapes and identical sizes and are formed so as to entirely and mutually overlap in the Y′-axis direction. While it is not illustrated in FIG. 1A and FIG. 1B, and details will be described later with reference to FIG. 3A and FIG. 3B, the excitation electrode 142 includes a main thickness portion, a flat portion, and, in some cases, an inclined portion. The piezoelectric vibrating piece 140 is placed on the placement surface 112b such that the extraction electrodes 143 are electrically connected to the connection electrodes 115 via conductive adhesives (not illustrated).

[Configuration of M-SC-Cut]

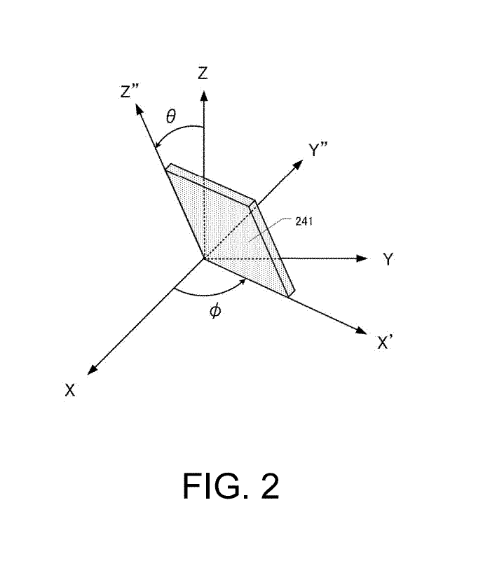

FIG. 2 is an explanatory drawing of an M-SC (Modified-SC)-cut quartz-crystal material. FIG. 2 denotes crystallographic axes for a crystal as an X-axis, a Y-axis, and a Z-axis. The M-SC cut quartz-crystal material is one type of twice-rotated cut quartz-crystal materials and corresponds to an X′Z″-cut plate obtained by rotating an XZ-cut plate of the crystal around the Z-axis of the crystal by ϕ degree and further rotating an X′Z-cut plate generated by the rotation around an X′-axis by θ degree. In the case of the M-SC-cut, ϕ is approximately 24 degrees, and θ is approximately 34 degrees. FIG. 2 denotes new axes for the crystal element generated by the above-described twice-rotation as the X′-axis, a Y″-axis, and a Z″-axis. A twice-rotated cut piezoelectric substrate 241, which is cut out as described above, is a quartz-crystal material a main vibration of which is, what is called, a C mode and a B mode that have a shear displacement propagating in a thickness direction. The twice-rotated cut crystal element includes, other than an SC-cut, the crystal element such as an IT-cut where ϕ is approximately 19 degrees, and θ is approximately 34 degrees. The vibrations of these C mode and B mode are classified into a thickness-shear vibration mode similarly to an AT-cut. Forming excitation electrodes and extraction electrodes similarly to FIG. 1A and FIG. 1B ensures application of the embodiment as a piezoelectric vibrating piece 240.

[Configuration of Excitation Electrode]

FIG. 3A and FIG. 3B are drawings for illustrating, in particular, a structure of the excitation electrodes of the piezoelectric vibrating piece 140 or 240. In particular, FIG. 3A is a plan view of the piezoelectric vibrating piece 140 or 240, and FIG. 3B is a partial sectional drawing taken along the line IIIB-IIIB in FIG. 3A. Both the drawings indicate coordinate symbols for the respective cases of the AT-cut and the M-SC-cut (indicated with parentheses).

Since any of the piezoelectric vibrating pieces 140 and 240 results in a similar description, in the following description, a description will be given by using the M-SC-cut piezoelectric vibrating piece 240. The piezoelectric substrate 241 is a flat plate shaped substrate that has a rectangular flat surface having long sides extending in the X′-axis direction and short sides extending in the Z″-axis direction. Excitation electrodes 242 formed on the principal surfaces on the +Y″-axis side and the −Y′-axis side of the piezoelectric substrate 241 are formed in a circular shape. The respective excitation electrodes 242 include main thickness portions 242a and flat portions 242b. The main thickness portion 242a is formed to have a constant thickness. The flat portion 242b is formed to have a constant width in a peripheral area of the main thickness portion 242a and to have a constant thickness that is thinner than the main thickness portion 242a. Furthermore, the respective excitation electrodes 242 include first inclined portions 242c and second inclined portions 242d. The first inclined portion 242c is inclined with respect to the principal surface from a portion contacting the main thickness portion 242a to the flat portion 242b. The second inclined portion 242d is inclined with respect to the principal surface from the flat portion 242b to an outermost periphery of the excitation electrode 242.

In this embodiment, the main thickness portion 242a of the excitation electrode 242 is formed to have a thickness of YA. Specifically, in this embodiment, it is forming to have 140 nm (1400 Å). The flat portion 242b is formed to have a height of YB. Specifically, in this embodiment, it is formed to have 70 nm (700 Å). These main thickness portion and flat portion are formed by, typically, sputtering by using a metal mask for electrode formation or a vacuum evaporation method. Using these forming methods cause metal particles generated by sputtering or evaporation to enter a gap between the mask and the piezoelectric substrate 241 and thus form the first inclined portion 242c and the second inclined portion 242d. A width from an end of the main thickness portion 242a to the outermost periphery of the excitation electrode 242 is formed to be XL, a width of the first inclined portion 242c is formed to be XA, a width of the flat portion 242b is formed to be XB, and a width of the second inclined portion 242d is formed to be XC. Some film forming devices are less likely to form an inclination. The device that the inventor uses has shown that a width (XA+XC), which is a sum of the above-described XA and XC, is approximately 70 μm. That is, when a flexure vibration as the unnecessary vibration, which will be described later, has a wavelength of 140 μm, it has been founded that XA+XC=70 μm in this case is XA+XC<1λ.

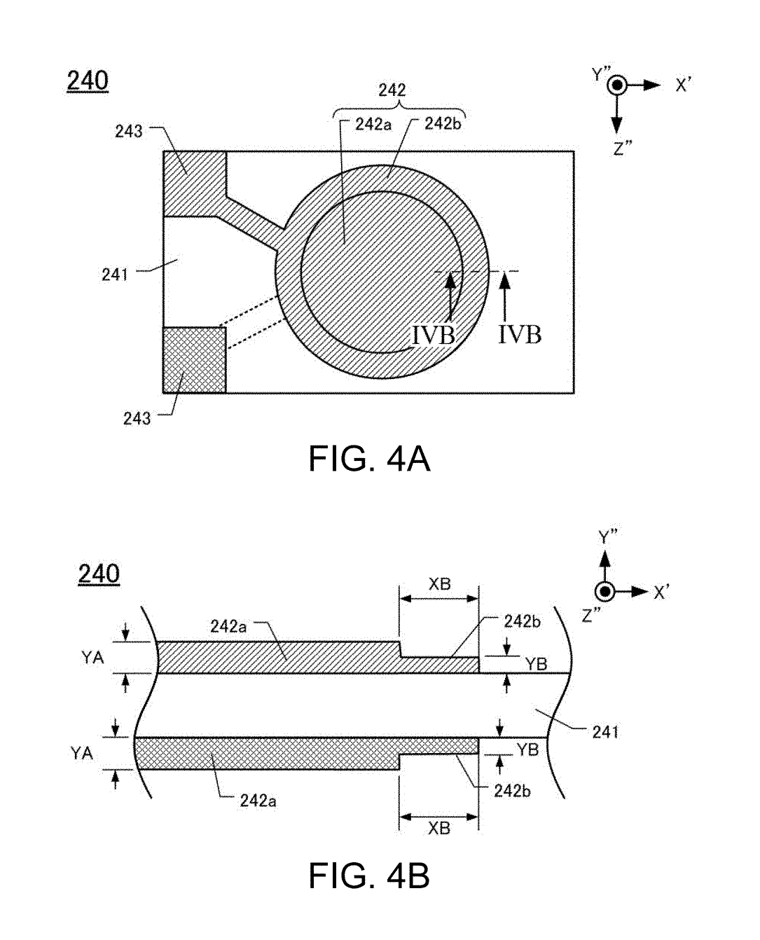

In some cases, as illustrated in FIG. 4A and FIG. 4B, there also exists a piezoelectric device that has a structure hardly having the first inclined portion 242c and the second inclined portion 242d, which are illustrated in FIG. 3A and FIG. 3B. In a case where the excitation electrode is formed by using, for example, an evaporation method, the mask and the piezoelectric substrate have a close contact, and metal particles straightly reach the piezoelectric substrate, or similar case, the first inclined portion 242c and the second inclined portion 242d are hardly formed.

In the above-described various kinds of piezoelectric devices vibrating in thickness-shear vibration mode, when the width XA or XC of the inclined portion is large compared with the wavelength of the flexure vibration as the unnecessary vibration generated in the piezoelectric device, namely, in the above description, when the width of the inclined portion can be made relatively large by forming the excitation electrode with sputtering, a suppression effect of the flexure vibration is easily obtained, and thus this ensures the reduced deterioration of piezoelectric device properties; otherwise a problem occurs. In contrast to this, according to the study by the inventor of this application, the following has been found. Although the used piezoelectric substrate 241 is a flat plate-shaped substrate on which processing such as bevel processing or convex processing is not performed, even the piezoelectric device having the excitation electrode 242 including the main thickness portion 242a, the first inclined portion 242c, the flat portion 242b, and the second inclined portion 242d, which are described by using FIG. 3A and FIG. 3B, or even the piezoelectric device having the excitation electrode 242 including the main thickness portion 242a and the flat portion 242b, which are described by using FIG. 4A and FIG. 4B, restricts the occurrence of the vibration energy loss by properly setting the flat-portion width as the following description.

### First Example: Flat-Portion Width of Piezoelectric Vibrating Piece 240 and Vibration Energy Loss

[Fundamental Wave Simulation]

The Following describes simulation results on the vibration energy loss of the piezoelectric vibrating piece 240 formed of M-SC-cut quartz-crystal material. This simulation employs a model with a fundamental wave 20 MHz.

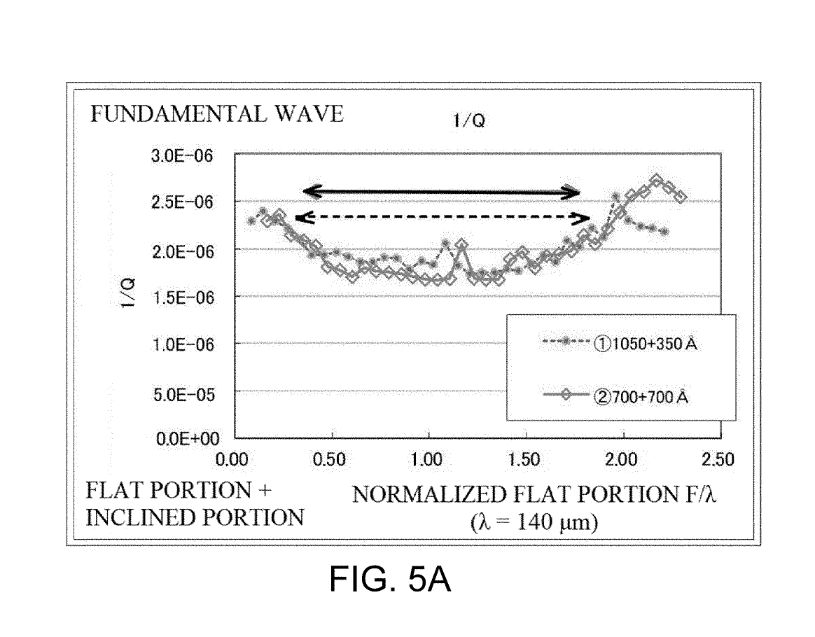

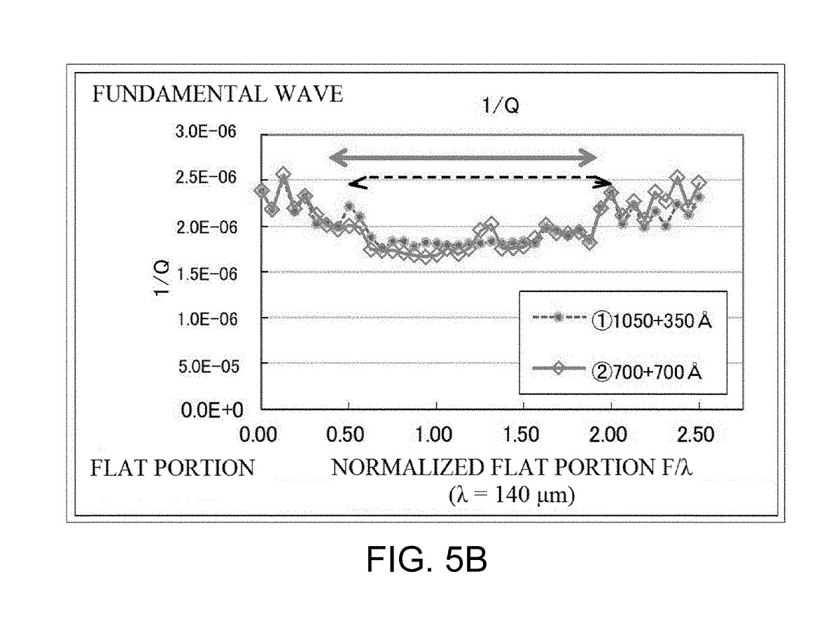

FIG. 5A and FIG. 5B are graphs showing a relationship between the width XB of the flat portion 242b of the piezoelectric vibrating piece 240 and the vibration energy loss (1/Q) of the main vibration. The graph in FIG. 5A is a graph of the excitation electrode including the flat portion 242b, the first inclined portion 242c, and the second inclined portion 242d, which are illustrated in FIG. 3B. The graph in FIG. 5B is a graph of the excitation electrode including the flat portion 242b and almost no inclined portion, which are illustrated in FIG. 4B.

As an analytical model, FIG. 5A and FIG. 5B show calculation results by the simulations in the case of a model where the whole excitation electrode is made of gold (Au), the main thickness portion 242a has a film thickness YA of 140 nm (1400 Å), and a frequency of the main vibration is the fundamental wave 20 MHz. The examples where the flat portion 242b has the film thicknesses YB of 105 nm (1050 Å) and 70 nm (700 Å) are shown. In the graphs in FIG. 5A and FIG. 5B, the description of 1050+350 Å denotes that the flat portion 242b has the film thickness YB of 1050 Å and the thickness from the surface of the flat portion 242b to the surface of the main thickness portion 242a is 350 Å. The description of 700+700 Å denotes that the flat portion 242b has the film thickness YB of 700 Å and the thickness from the surface of the flat portion 242b to the surface of the main thickness portion 242a is 700 Å. The piezoelectric vibrating piece 240 including the excitation electrode of 1050+350 Å is indicated with a dotted line and circle marks. The piezoelectric vibrating piece 240 including the excitation electrode of 700+700 Å is indicated with a solid line and square marks.

In the piezoelectric vibrating piece, an unnecessary vibration that is a vibration different from the main vibration (for example, the C mode) and unintended in design is generated along with the main vibration. In the piezoelectric vibrating piece including the piezoelectric substrate that is made of the quartz-crystal material such as an SC-cut quartz-crystal material and vibrates in the thickness-shear vibration mode, an influence caused by, in particular, a flexure vibration is large as an unnecessary vibration. In the graphs in FIG. 5A and FIG. 5B, horizontal axes indicate the flat-portion width XB that is normalized by a flexural wavelength λ (=approximately 140 μm) as the wavelength of the flexure vibration. Thus, in the graphs in FIG. 5A and FIG. 5B, an actual dimension of the flat-portion width denoted as “1” is 1×λ; in the piezoelectric vibrating piece 240, the flat-portion width denoted as 1.00 is 1×λ=approximately 140 μm. In the graphs in FIG. 5A and FIG. 5B, vertical axes indicate a reciprocal of a Q factor that denotes the vibration energy loss of the main vibration. In FIG. 5A, as the width XA of the first inclined portion 242c and the width XC of the second inclined portion 242d (see FIG. 3B), the analytical model sets each of XA and XC to be 35 μm and thus (XA+XC)=70 μm.

In the piezoelectric vibrating piece including the inclined portion, which is illustrated in FIG. 5A, both the piezoelectric vibrating piece 240 including the excitation electrode of 1050+350 Å and the piezoelectric vibrating piece 240 including the excitation electrode of 700+700 Å show the low vibration energy loss 1/Q as 2.5×10⁶ or less in the range where the width XB, which is normalized by the flexural wavelength λ, of the flat portion 242b is approximately from “0.3” to “2.” That is, it is seen that forming the width XB of the flat portion 242b to have the length of 0.3 times or more and 2 times or less of the flexural wavelength λ reduces the vibration energy loss. Specifically, the piezoelectric vibrating piece 240 including the excitation electrode of 1050+350 Å shows a low magnitude of 1/Q and further a reduced variation, in the range where the width XB, which is normalized by the flexural wavelength λ, of the flat portion 242b is from “0.33” to “1.77.” The piezoelectric vibrating piece 240 including the excitation electrode of 700+700 Å shows a low magnitude of 1/Q and further the reduced variation, in the range where the width XB, which is normalized by the flexural wavelength λ, of the flat portion 242b is from “0.35” to “1.73.” That is, it is seen that when the width XB of the flat portion 242b is formed to have the length of from 0.35 times to 1.73 times of the flexural wavelength λ, the vibration energy loss stably lowers.

In the flexure vibration, since the vibration energy is converted into the flexure vibration at mainly an end portion of the excitation electrode, and the flexure vibration is superimposed on the main vibration to vibrate in the entire piezoelectric vibrating piece, the vibration energy is absorbed into a conductive adhesive holding the piezoelectric vibrating piece. Such energy loss due to the flexure vibration leads to the vibration energy loss. In the piezoelectric vibrating piece 240 including the inclined portion, it is considered that forming the width XB of the flat portion 242b to have a length of 0.35 times or more and 1.73 times or less of the flexural wavelength λ ensures the reduced occurrence of the flexure vibration. This ensures the reduced vibration energy loss.

In the piezoelectric vibrating piece including no inclined portion, which is illustrated in FIG. 5B, both the piezoelectric vibrating piece 240 including the excitation electrode of 1050+350 Å and the piezoelectric vibrating piece 240 including the excitation electrode of 700+700 Å shows the low magnitude of the vibration energy loss 1/Q as 2.5×10⁻⁶ or less, in the range where the width XB, which is normalized by the flexural wavelength λ, of the flat portion 242b is from approximately “0.3” to “2.” That is, it is seen that forming the width XB of the flat portion 242b to have the length of 0.3 times or more and 2 times or less of the flexural wavelength λ reduces the vibration energy loss. Specifically, the piezoelectric vibrating piece 240 including the excitation electrode of 1050+350 Å shows the low magnitude of 1/Q and further the reduced variation, in the range where the width XB, which is normalized by the flexural wavelength λ, of the flat portion 242b is from “0.63” to “1.88.” The piezoelectric vibrating piece 240 including the excitation electrode of 700+700 Å shows the low magnitude of 1/Q and further the reduced variation, in the range where the width XB, which is normalized by the flexural wavelength λ, of the flat portion 242b is from “0.38” to “1.88.” That is, it is seen that when the width XB of the flat portion 242b is formed to have the length of from 0.63 times to 1.88 times of the flexural wavelength λ, the vibration energy loss stably lowers.

In the piezoelectric vibrating piece 240 including no inclined portion, it is considered that forming the width XB of the flat portion 242b to have the length of 0.63 times or more and 1.88 times or less of the flexural wavelength λ ensures the reduced occurrence of the flexure vibration. This ensures the reduced vibration energy loss.

When taking the flat-portion width normalized by the flexural wavelength λ into account, it is considered that a trend and the magnitude of 1/Q are stable regardless of difference of the piezoelectric material employed for the piezoelectric substrate. Therefore, while in the first example the cases of the AT-cut quartz-crystal material and the M-SC-cut quartz-crystal material are indicated, it is not limited to these quartz-crystal materials; even when another quartz-crystal material vibrating in the thickness-shear vibration mode, such as the SC-cut or the IT-cut quartz-crystal material, is employed or even when another piezoelectric material vibrating in the thickness-shear vibration mode, for example, LiNbO₃, LiTaO₄, GaPO₄, or a piezoelectric ceramic material is employed, it is considered that 1/Q lowers in a range of an inclination width similar to the piezoelectric vibrating piece 240.

[Experimental Production of Piezoelectric Vibrating Piece 240]

FIG. 5A and FIG. 5B show simulation results regarding the vibration energy loss of the piezoelectric vibrating piece 240 including the excitation electrode of 1050+350 Å and the piezoelectric vibrating piece 240 including the excitation electrode of 700+700 Å. Based on this simulation, the inventor experimentally produced the piezoelectric vibrating piece 240 having a main vibration frequency of 20 MHz. The following describes processes to form the excitation electrode 242 by an evaporation method in the piezoelectric substrate 241 illustrated in FIG. 3A and FIG. 3B.

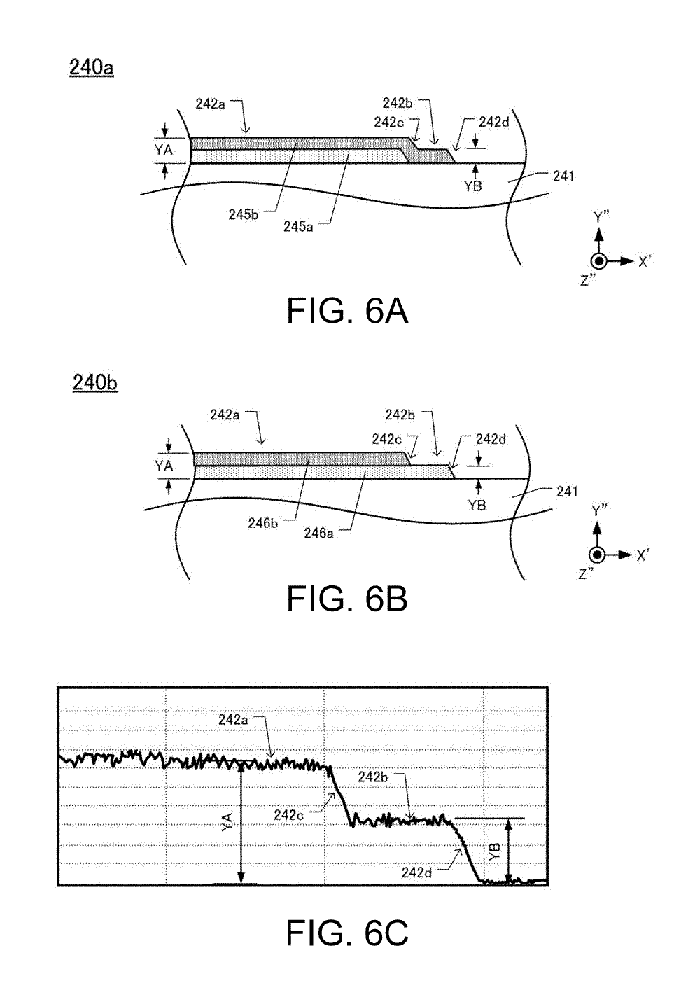

FIG. 6A is a partial sectional drawing of the piezoelectric vibrating piece 240 (240a) fabricated by a first method. FIG. 6A is a partial sectional drawing including a cross section corresponding to the cross section taken along the line IIIB-IIIB in FIG. 3A. In the excitation electrode 242 of the piezoelectric vibrating piece 240a, by using a first mask (not illustrated) having a first opening (such as ϕ2.1 mm), a first layer 245a is formed by a deposition of evaporation particles onto the piezoelectric substrate 241. Subsequently, by using a second mask (not illustrated) having a second opening (such as ϕ2.4 mm), a second layer 245b is formed by the deposition of evaporation particles onto the first layer 245a and the piezoelectric substrate 241 such that it covers the first layer 245a. The forming processes ensure forming the first inclined portion 242c and the second inclined portion 242d. While the detail will be described later by using FIG. 6C, the first inclined portion 242c and the second inclined portion 242d each had the width of approximately 35 μm, and the sum of the widths of both the inclined portions was approximately 70 μm. That is, when normalized by the above-described wavelength λ (in this case, λ=140 μm) of the flexure vibration, the widths of the respective inclined portions are 1λ or less, more specifically, less than 0.5λ, and the sum of the widths of both inclined portions is also 1λ or less. While FIG. 6A illustrates only two layers, the illustration of a base layer, such as a chrome film, that is ordinarily disposed so as to ensure adhesion of the piezoelectric substrate 241 with gold (Au) for the excitation electrode is omitted.

FIG. 6B is a partial sectional drawing of the piezoelectric vibrating piece 240 (240b) that is fabricated by a second method. FIG. 6B is also a partial sectional drawing including a cross section corresponding to the cross section taken along the line IIIB-IIIB in FIG. 3A. That is, a different point from the above-described first method is that the second method is a method to form the layers such that an area of a lower layer is made larger to make the area of an upper layer smaller than the lower layer. Specifically, in the excitation electrode 242 of the piezoelectric vibrating piece 240b, a first layer 246a is formed by adhering target atoms to the piezoelectric substrate 241 by using the second mask (not illustrated) having the second opening (such as ϕ2.4 mm). Also in this example, the vacuum evaporation method was employed. Also in the case of this example, when normalized by the above-described λ, each of the widths of the first inclined portion 242c and the second inclined portion 242d may be 1λ or less. Specifically, each of the widths is approximately 0.47λ, and the sum of the widths of both the inclined portions is preferred to be 1λ or less. Only any one of the first inclined portion 242c or the second inclined portion 242d may be formed. The illustration of chrome film or similar film used to ensure adhesion is omitted.

FIG. 6C is a graph where the thicknesses and shapes of the excitation electrodes formed as described above by an analytical method using an energy-dispersive X-ray spectrometer (EDS) were actually measured. The graph indicates surface heights in the cross section taken along the line IIIB-IIIB in FIG. 3A. The upper-side line on the left side indicates a region of the main thickness portion 242a, and it indicates the region of the first inclined portion 242c on its way to proceed toward the right. Furthermore, it reaches the region indicating the flat portion 242b from the first inclined portion 242c. Proceeding further to the right reaches the region indicating the second inclined portion 242d.

[Confirmation of Effect of Embodiment by Reassembling Experiment]

To confirm the effect of the embodiment, the inventor performed the following experiment. First, by using a mask having an opening diameter of 2.4 mm, and with a vacuum evaporation method, 9 pieces of piezoelectric devices of a comparative example that include an excitation electrode that is a simple-one-layer having no main thickness portion and no flat portion and having a thickness of 140 nm were fabricated. Subsequently, crystal impedance (CI) temperature characteristics were measured on the respective 9 pieces of piezoelectric devices in a range of −40° C. to 120° C. Subsequently, the 9 pieces of piezoelectric devices of the comparative example were once dismantled and the piezoelectric substrates were reconditioned. With the reconditioned piezoelectric substrates, piezoelectric devices of a working example including the main thickness portion, the flat portion, and the inclined portion, which have been described by using FIG. 3A and FIG. 3B were fabricated. Then, the crystal impedance (CI) temperature characteristics were measured on each of the 9 pieces of piezoelectric devices of the working example in a range of −40° C. to 120° C. In a reassembly from the comparative example to the working example and examination of the CI temperature characteristics, the 9 pieces of the piezoelectric substrates were reassembled on one-to-one basis, and change conditions of the CI temperature characteristics were traced.

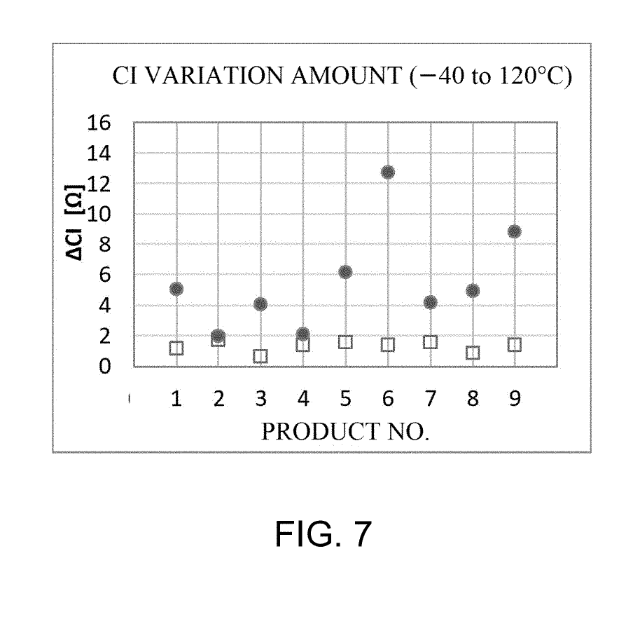

FIG. 7 has a horizontal axis indicating product numbers of the above-described 9 pieces of the piezoelectric devices, namely, the numbers of the piezoelectric substrates where the numbers are managed and a vertical axis indicating a difference ΔCI (Ω) between a largest CI value and a smallest CI value of the respective piezoelectric devices in a range of −40° C. to 120° C., and has plotted the relationship between both of them. In the drawing, square marks indicate CI variation amounts of the working example (reassembled product), namely, the piezoelectric vibrating piece 240, and circle marks indicate the CI variation amounts of the piezoelectric devices of the comparative example (before reassembly).

The CI variation amounts of the 9 pieces of the piezoelectric vibrating pieces 240 that were reassembled with an electrode structure of the embodiment are all stably 2Ω or less. On the other hand, the CI variation amounts of the 9 pieces of the comparative piezoelectric vibrating pieces have dispersion from 2Ω to 13Ω, and an average of the 9 pieces of the CI variation amounts are high as 6Ω. That is, while a temperature change causes the comparative piezoelectric vibrating piece to generate the unnecessary vibration to significantly vary the CI values, the piezoelectric vibrating piece 240 has the stable CI values and ensures stable oscillation of 20 MHz.

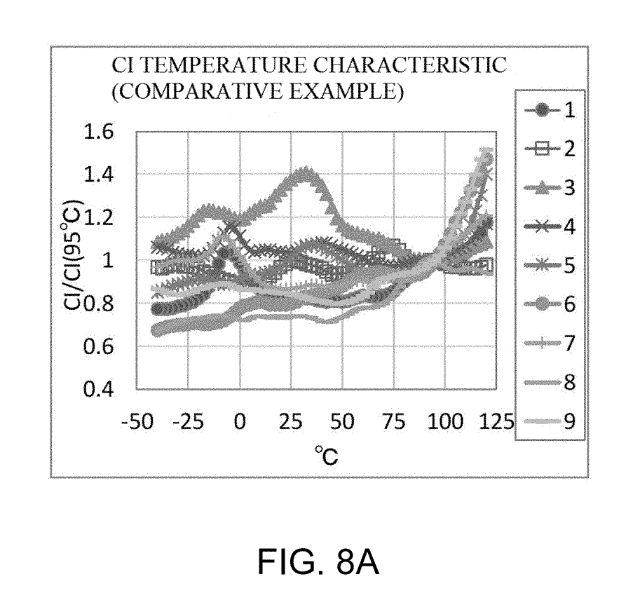

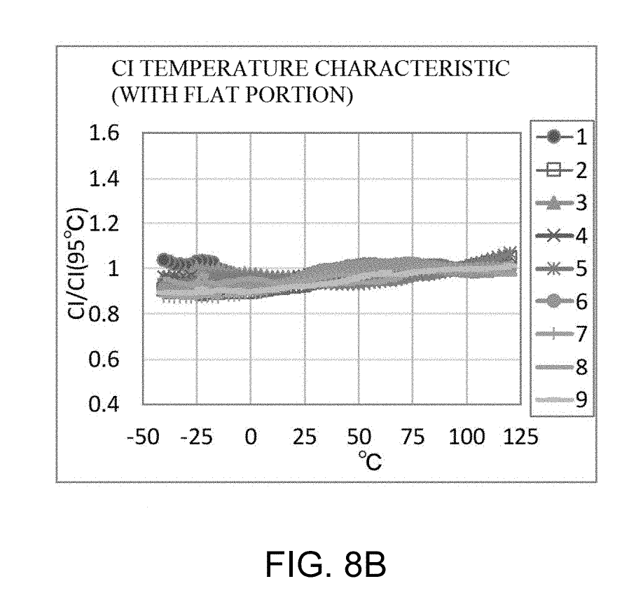

FIG. 8A is a drawing illustrating a whole picture of CI temperature characteristics of the 9 pieces of the piezoelectric devices of the comparative example. FIG. 8B is a drawing illustrating a whole picture of the CI temperature characteristics of the 9 pieces of the piezoelectric devices of the working example, which were reassembled with the electrode structure of the embodiment. The vertical axes of both the drawings indicate CI/CI (95° C.) that is a value where the CI value at the respective temperatures is normalized based on a CI value at the temperature of 95° C. From FIG. 8A and FIG. 8B, it is seen that the structure of the embodiment ensures contributing to stabilization of the piezoelectric device characteristics.

### Second Example: Flat-Portion Width of Piezoelectric Vibrating Piece 240 and Vibration Energy Loss

[Fifth Harmonic Simulation]

The following describes the simulation results regarding the vibration energy loss of the piezoelectric vibrating piece 240 fabricated by the M-SC-cut and the IT-cut quartz-crystal materials. The simulation employs a model with the fifth harmonic 21.64 MHz.

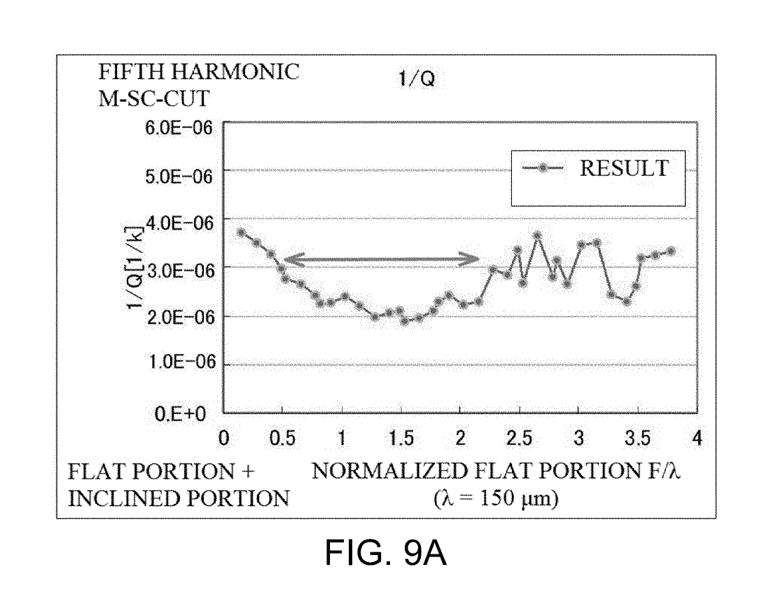

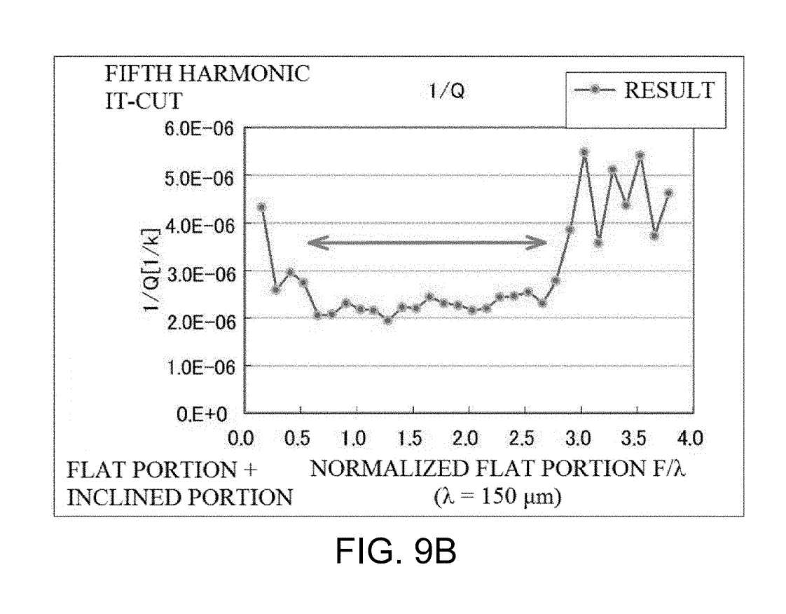

FIG. 9A and FIG. 9B are graphs indicating the relationships between the width XB of the flat portion 242b of the piezoelectric vibrating piece 240 and the vibration energy loss (1/Q) of the main vibration. Both FIG. 9A and FIG. 9B illustrate the piezoelectric vibrating pieces that include the excitation electrode including the flat portion 242b, the first inclined portion 242c, and the second inclined portion 242d, which are illustrated in FIG. 3A. In the analytical model of FIG. 9A and FIG. 9B, as the width XA of the first inclined portion 242c and the width XC of the second inclined portion 242d (see FIG. 3B), XA and XC are each set to be 35 μm, and thus (XA+XC)=70 μm.

As the analytical model, FIG. 9A and FIG. 9B indicate a case where the whole excitation electrode is made of gold (Au), the film thickness YA of the main thickness portion 242a is 140 nm (1400 Å), and the film thickness YB of the flat portion 242b is 70 nm (700 Å). The graph in FIG. 9A is a graph of the M-SC-cut, and the graph in FIG. 9B is a graph of the IT-cut.

In the piezoelectric vibrating piece, an unnecessary vibration that is a vibration different from the main vibration (for example, the C mode) and unintended in design is generated along with the main vibration. In the piezoelectric vibrating piece including the piezoelectric substrate that is made of the quartz-crystal material such as the SC-cut or the IT-cut quartz-crystal material and vibrates in the thickness-shear vibration mode, an influence caused by, in particular, a flexure vibration is large as an unnecessary vibration. In the graphs in FIG. 9A and FIG. 9B, horizontal axes indicate the flat-portion width XB that is normalized by a flexural wavelength λ (=approximately 150 μm) as the wavelength of the flexure vibration. Thus, in the graphs in FIG. 9A and FIG. 9B, an actual dimension of the flat-portion width denoted as “1” is 1×λ; in the piezoelectric vibrating piece 240, the flat-portion width denoted as 1.00 is 1×λ=approximately 150 μm. In the graphs in FIG. 9A and FIG. 9B, vertical axes indicate a reciprocal of a Q factor that denotes the vibration energy loss of the main vibration.

In the M-SC-cut piezoelectric vibrating piece illustrated in FIG. 9A, the piezoelectric vibrating piece 240 including the excitation electrode of 700+700 Å shows the low magnitude of the vibration energy loss 1/Q as 3.0×10⁻⁶ or less, in the range where the width XB, which is normalized by the flexural wavelength λ, of the flat portion 242b is from approximately “0.5” to “2.25.” That is, it is seen that forming the width XB of the flat portion 242b to have the length of 0.5 times or more and 2.25 times or less of the flexural wavelength λ reduces the vibration energy loss.

In the IT-cut piezoelectric vibrating piece illustrated in FIG. 9B, the piezoelectric vibrating piece 240 including the excitation electrode of 700+700 Å shows the low magnitude of the vibration energy loss 1/Q as 3.0×10⁻⁶ or less, in the range where the width XB, which is normalized by the flexural wavelength λ, of the flat portion 242b is from approximately “0.5” to “2.5.” That is, it is seen that forming the width XB of the flat portion 242b to have the length of 0.5 times or more and 2.5 times or less of the flexural wavelength λ reduces the vibration energy loss. While there are some differences between the range of the M-SC-cut piezoelectric vibrating piece and the range of the IT-cut piezoelectric vibrating piece, those ranges are approximately similar.

By forming the width XB of the flat portion 242b to have the length of 0.5 times or more and 2.25 times or less of the flexural wavelength λ, it is considered that the twice-rotated cut piezoelectric vibrating piece 240 on the fifth harmonic ensures the reduced occurrence of the flexure vibration, and thus this ensures the reduced vibration energy loss.

When taking the flat-portion width normalized by the flexural wavelength λ into account, it is considered that a trend and the magnitude of 1/Q are stable regardless of difference of the piezoelectric material employed for the piezoelectric substrate. Therefore, while in the second example the cases of the fifth harmonics of the M-SC-cut quartz-crystal material and the IT-cut quartz-crystal material are indicated, it is not limited to these quartz-crystal materials; even when another quartz-crystal material vibrating in thickness-shear vibration mode, such as the SC-cut or the AT-cut quartz-crystal material, is employed or even when another piezoelectric material vibrating in thickness-shear vibration mode, for example, LiNbO₃, LiTaO₄, GaPO₄, or a piezoelectric ceramic material is employed, it is considered that 1/Q lowers in a range of an inclination width similar to the piezoelectric vibrating piece 240 on the fifth harmonic.

The preferred embodiments of this disclosure have been described above in detail. It is apparent to those skilled in the art that a variety of variation and modification of the embodiment can be made within the technical scope of this disclosure.

For example, while the descriptions have been given of the main thickness portion having the film thickness YA of 140 nm (1400 Å) of the excitation electrode, it was confirmed that even 100 nm to 200 nm could be applicable. While in this embodiment the outer shape of the excitation electrode is formed in a circular shape, it is not required to limit to a circular shape and it may be formed in an elliptical shape.

The piezoelectric vibrating piece of a second aspect includes a piezoelectric substrate and excitation electrodes. The piezoelectric substrate is formed in a flat plate shape. The piezoelectric substrate vibrates in a thickness-shear vibration mode. The excitation electrodes are formed on respective both principal surfaces of the piezoelectric substrate. Then, the excitation electrodes each include a main thickness portion and a flat portion. The main thickness portion has a first thickness. The flat portion is formed in a peripheral area of the main thickness portion. The flat portion has a predetermined width having a second thickness that is thinner than the first thickness between from a portion contacting the main thickness portion to an outermost periphery of the excitation electrode. Then, the predetermined width of the flat portion is formed to have a length of 0.35 times or more and 1.73 times or less of a flexural wavelength. The flexural wavelength is a wavelength of a flexure vibration as an unnecessary vibration.

The piezoelectric vibrating piece of a third aspect further includes a first inclined portion and a second inclined portion. The first inclined portion is inclined with respect to the principal surface from the portion contacting the main thickness portion to the flat portion. The second inclined portion is inclined with respect to the principal surface from the flat portion to the outermost periphery of the excitation electrode. Then, at least any one of a width of the first inclined portion from the portion contacting the main thickness portion to the flat portion and a width of the second inclined portion from the flat portion to the outermost periphery of the excitation electrode is formed to be 1λ or less of the flexural wavelength. The flexural wavelength is a wavelength of the flexure vibration as the unnecessary vibration. Alternatively, each of the width of the first inclined portion from the portion contacting the main thickness portion to the flat portion and the width of the second inclined portion from the flat portion to the outermost periphery of the excitation electrode is formed to be 1λ or less of the flexural wavelength. The flexural wavelength is a wavelength of the flexure vibration as the unnecessary vibration.

As another aspect, the main thickness portion may be formed to have a thickness of between 100 nm and 200 nm. The excitation electrode may have an outer shape formed in a circular shape or an elliptical shape. Moreover, as a fourth aspect, there may be provided a piezoelectric device that includes the piezoelectric vibrating piece of the above-described first aspect and similar aspect, and a package in which the piezoelectric vibrating piece is placed.

The piezoelectric vibrating piece and the piezoelectric device of the disclosure ensure the reduced occurrence of the unnecessary vibration.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric vibrating piece, comprising:
a piezoelectric substrate, formed in a flat plate shape, and the piezoelectric substrate vibrating in a thickness-shear vibration mode; and
excitation electrodes, formed on respective both principal surfaces of the piezoelectric substrate, wherein
the excitation electrodes each include a main thickness portion and a flat portion,
the main thickness portion having a first thickness,
the flat portion being formed in a peripheral area of the main thickness portion, the flat portion having a second thickness that is thinner than the first thickness between from a portion contacting the main thickness portion to an outermost periphery of the excitation electrode, and
the flat portion having the second thickness extends from the portion contacting the main thickness portion to the outermost periphery of the excitation electrode,
the flat portion having a width formed to have a length of 0.63 times or more and 1.88 times or less of a flexural wavelength, the flexural wavelength being a wavelength of a flexure vibration as an unnecessary vibration.

2. A piezoelectric vibrating piece, comprising:
a piezoelectric substrate, formed in a flat plate shape, and the piezoelectric substrate vibrating in a thickness-shear vibration mode; and
excitation electrodes, formed on respective both principal surfaces of the piezoelectric substrate, wherein
the excitation electrodes each include a main thickness portion and a flat portion,
the main thickness portion having a first thickness,
the flat portion having a second thickness that is thinner than the first thickness, and
the flat portion having the second thickness has a width foil ied to have a length of 0.35 times or more and 1.73 times or less of a flexural wavelength, the flexural wavelength being a wavelength of a flexure vibration as an unnecessary vibration.

3. The piezoelectric vibrating piece according to claim 2, wherein
the piezoelectric vibrating piece includes a first inclined portion and a second inclined portion,
the first inclined portion being inclined with respect to the principal surface from a portion contacting the main thickness portion to the flat portion,
the second inclined portion being inclined with respect to the principal surface from the flat portion to an outermost periphery of the excitation electrode.

4. The piezoelectric vibrating piece according to claim 1, wherein
the main thickness portion is formed to have a thickness of between 100 nm and 200 nm.

5. The piezoelectric vibrating piece according to claim 1, wherein
the excitation electrode has an outer shape formed in a circular shape or an elliptical shape.

6. The piezoelectric vibrating piece according to claim 1, wherein
the piezoelectric substrate vibrates in a fundamental wave.

7. A piezoelectric vibrating piece, comprising:
a piezoelectric substrate, formed in a flat plate shape, and the piezoelectric substrate vibrating in a thickness-shear vibration mode and an overtone mode of a fifth harmonic; and
excitation electrodes, formed on respective both principal surfaces of the piezoelectric substrate, wherein
the excitation electrodes each include a main thickness portion, a first inclined portion, a flat portion, and a second inclined portion,
the main thickness portion having a first thickness,
the first inclined portion being inclined with respect to the principal surface from a portion contacting the main thickness portion,
the flat portion having a second thickness that is thinner than the first thickness from the first inclined portion,
the second inclined portion being inclined with respect to the principal surface from the flat portion to an outermost periphery of the excitation electrode, and
the flat portion has a width formed to have a length of 0.50 times or more and 2.25 times or less of a flexural wavelength, the flexural wavelength being a wavelength of a flexure vibration as an unnecessary vibration.

8. The piezoelectric vibrating piece according to claim 3, wherein
at least any one of a width of the first inclined portion from the portion contacting the main thickness portion to the flat portion and a width of the second inclined portion from the flat portion to the outermost periphery of the excitation electrode is formed to be 1λ or less of the flexural wavelength,
the flexural wavelength being a wavelength of a flexure vibration as an unnecessary vibration.

9. The piezoelectric vibrating piece according to claim 3, wherein
each of a width of the first inclined portion from the portion contacting the main thickness portion to the flat portion and a width of the second inclined portion from the flat portion to the outermost periphery of the excitation electrode is formed to be 1λ or less of the flexural wavelength,
the flexural wavelength being a wavelength of a flexure vibration as an unnecessary vibration.

10. A piezoelectric device, comprising:
the piezoelectric vibrating piece according to of claim 1; and
a package in which the piezoelectric vibrating piece is placed.
